(19) United States
(12) Patent Application Publication
(10) Pub. No.: US 2026/0190878 A1
(43) Pub. Date: Jul. 2, 2026

(54) TRANSISTOR STRUCTURES HAVING IMPROVED CONTACT EPITAXIAL LAYERS AND METHOD OF MANUFACTURING THEREOF

(71) Applicant: Taiwan Semiconductor Manufacturing Company, Ltd., Hsinchu (TW)

(72) Inventors: Yu-Hsing LIN, Hsinchu (TW); Chun Wei CHEN, Hsinchu (TW); Yen CHUANG, Hsinchu (TW); Chien-Chia CHENG, Hsinchu (TW); Ming-Hua YU, Hsinchu (TW)

(73) Assignee: Taiwan Semiconductor Manufacturing Company, Ltd., Hsinchu (TW)

(21) Appl. No.: 19/007,134

(22) Filed: Dec. 31, 2024

(51) Int. Cl. H01L 21/02; H01L 21/762; H10D 30/01; H10D 30/43; H10D 30/67; H10D 62/10; H10D 62/832

(52) U.S. Cl. CPC H10P 14/3411; H10D 30/014; H10D 30/43; H10D 30/6735; H10D 30/6757; H10D 62/121; H10D 62/124; H10D 62/832; H10P 14/24; H10W 10/014; H10W 10/17

(57) ABSTRACT

According to various embodiments, a method of forming a semiconductor device includes forming a gate-all-around field-effect transistor including a plurality of stacked channel layers and a source/drain region, performing a deposition process at a first temperature to form a first epitaxial layer over the source/drain region such that ends of the plurality of stacked channel layers are in contact with the first epitaxial layer, and performing a second deposition process at a second temperature to form a second epitaxial layer that is contacting the first epitaxial layer. In various embodiments, the second temperature is 20% to 30% lower than the first temperature. The resulting contact epitaxial layer is substantially free of dopant precipitates and includes fewer than 50 dislocations that each have a length that is from 1 nm to 40 nm, and subtend an angle that is between 20 degrees and 70 degrees relative to a [110] crystallographic plane.

### BACKGROUND

As the semiconductor industry advances into nanometer-scale technology nodes, driven by the need for higher device density, enhanced performance, and reduced costs, it has faced significant fabrication and design challenges. These challenges have led to the adoption of three-dimensional structures, such as multi-gate field-effect transistors (FETs), including fin field-effect transistors (FinFETs), gate-all-around field-effect transistors (GAA-FETs), and complementary FETs (CFET). In a FinFET, for example, the gate electrode interfaces with three sides of the channel region, separated by a gate dielectric layer. This configuration effectively provides control over the current flow through the channel, as the gate wraps around three of the channel's surfaces. However, the fourth side, which forms the bottom of the channel, remains distant from the gate electrode and thus experiences less effective gate control. In contrast, a GAA-FET features a gate electrode that surrounds all sides of the channel region, enabling more comprehensive depletion of the channel and resulting in reduced short-channel effects due to a steeper subthreshold swing and lower drain-induced barrier lowering. As transistor dimensions continue to shrink, further advancements in GAA-FET technology are necessary to meet the increasing demands of modern semiconductor devices.

### BRIEF DESCRIPTION OF THE DRAWINGS

The present disclosure is best understood from the following detailed description when read with the accompanying figures. It is emphasized that, per the standard practice in the industry, various features are not drawn to scale and are used for illustration purposes only. The dimensions of the various features may be arbitrarily increased or reduced for clarity of discussion.

FIG. 1A is a vertical cross-sectional view of a semiconductor device configured as a gate-all-around field-effect transistor (GAA FET), according to various embodiments.

FIG. 1B is a vertical cross-sectional view of a portion of a front contact of the semiconductor device of FIG. 1A, according to various embodiments

FIG. 1C is a vertical cross-sectional view of a portion of a back contact of the semiconductor device of FIG. 1A, according to various embodiments.

FIG. 2 is a vertical cross-sectional view of a structure that is used in the formation of a semiconductor device, according to various embodiments.

FIG. 3 is a vertical cross-sectional view of a structure that is used in the formation of a semiconductor device, according to various embodiments.

FIG. 4 is a vertical cross-sectional view of a structure that is used in the formation of a semiconductor device, according to various embodiments.

FIG. 5 is a vertical cross-sectional view of a structure that is used in the formation of a semiconductor device, according to various embodiments.

FIG. 6 is a vertical cross-sectional view of a structure that is used in the formation of a semiconductor device, according to various embodiments.

FIG. 7 is a vertical cross-sectional view of a structure that is used in the formation of a semiconductor device, according to various embodiments.

FIG. 8 is a vertical cross-sectional view of a structure that is used in the formation of a semiconductor device, according to various embodiments.

FIG. 9A is a vertical cross-sectional view of a structure that is used in the formation of a front contact in a semiconductor device, according to various embodiments.

FIG. 9B is a vertical cross-sectional view of a structure that is used in the formation of a front contact in a semiconductor device, according to various embodiments.

FIG. 9C is a vertical cross-sectional view of a structure that is used in the formation of a front contact in a semiconductor device, according to various embodiments.

FIG. 10A is a vertical cross-sectional view of a structure that is used in the formation of a back contact in a semiconductor device, according to various embodiments.

FIG. 10B is a vertical cross-sectional view of a structure that is used in the formation of a back contact in a semiconductor device, according to various embodiments.

FIG. 10C is a vertical cross-sectional view of a structure that is used in the formation of a back contact in a semiconductor device, according to various embodiments.

FIG. 10D is a vertical cross-sectional view of a structure that is used in the formation of a back contact in a semiconductor device, according to various embodiments.

FIG. 10E is a vertical cross-sectional view of a structure with front and back contacts in a semiconductor device, according to various embodiments.

FIG. 10F is a vertical cross-sectional view of a structure having an alternative configuration of the back contact, according to various embodiments.

FIG. 10G is a vertical cross-sectional view of a structure having an alternative configuration of the back contact, according to various embodiments.

FIG. 10H is a vertical cross-sectional view of a structure having an alternative configuration of the back contact, according to various embodiments.

FIG. 11A is a vertical cross-sectional view of a semiconductor device having crystal dislocations, according to various embodiments.

FIG. 11B is a vertical cross-sectional view of a semiconductor device having crystal dislocations, according to various embodiments.

FIG. 11C is a vertical cross-sectional view of a semiconductor device having crystal dislocations, according to various embodiments.

FIG. 11D is a vertical cross-sectional view of a semiconductor device having crystal dislocations and dopant precipitates, according to various embodiments.

FIG. 12A is a vertical cross-sectional view of a semiconductor device having dopant precipitates and/or amorphous regions, according to various embodiments.

FIG. 12B is a vertical cross-sectional view of a contact epitaxial layer having an amorphous region, according to various embodiments.

FIG. 12C is a vertical cross-sectional view of a contact epitaxial layer having a crystalline structure, according to various embodiments.

FIG. 12D is a vertical cross-sectional view of a contact epitaxial layer having dopant precipitates, according to various embodiments.

FIG. 12E is a vertical cross-sectional view of a contact epitaxial layer having an amorphous structure, according to various embodiments.

FIG. 13 is a flowchart illustrating operations of a method of forming a semiconductor device, according to various embodiments.

FIG. 14 is a flowchart illustrating operations of a method of forming a semiconductor device, according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous because they provide semiconductor device structures with improved source/drain features and improved contact epitaxial layers. In this regard a source/drain feature is formed by performing an epitaxial deposition process at a first temperature and a contact epitaxial layer is formed by performing a second epitaxial deposition process at a second temperature that is 20% to 30% lower than the first temperature. High-quality device structures, with few dislocations, amorphous material, and dopant precipitates are obtained by controlling process conditions according to various disclosed embodiments.

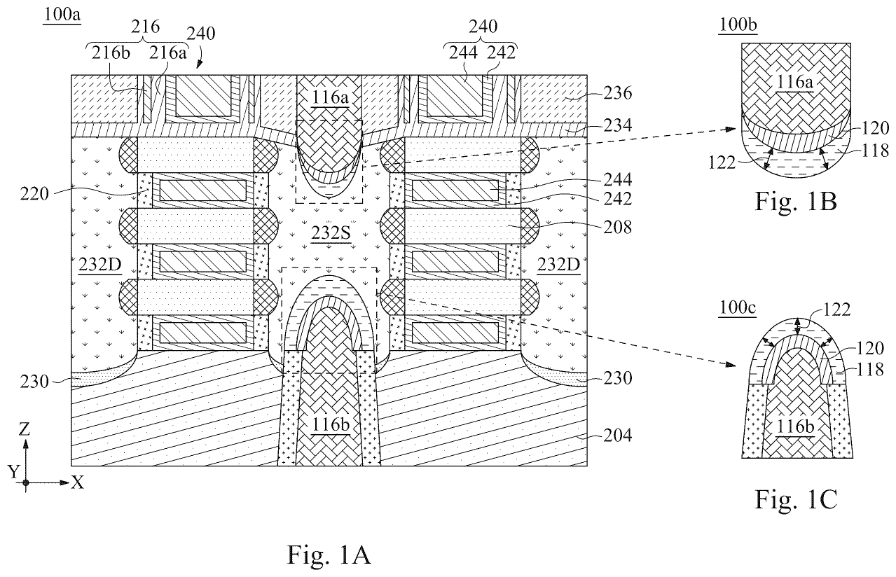

FIG. 1A is a vertical cross-sectional view of a portion of a semiconductor device 100a configured as a gate-all-around field-effect transistor (GAA-FET) device, according to various embodiments. The semiconductor device 100a includes a plurality of semiconductor nanostructure layers each configured as a channel layer 208. The semiconductor device 100a further includes a gate electrode layer 244 that surrounds each channel layer 208. The gate electrode layer 244 includes an electrically conductive material separated from the plurality of channel layers 208 by a gate dielectric layer 242.

The semiconductor device 100a further includes a source feature 232S and drain features 232D formed over ends of each of the plurality of channel layers 208. According to certain embodiments, the source feature 232S and the drain features 232D are similar structures and are referred to collectively as source/drain features 232. In other embodiments, the source feature 232S and the drain features 232D have dissimilar structures and compositions. According to various embodiments, the semiconductor device 100a is formed over a semiconductor layer 204. In this regard, the plane of the FIG. 1A intersects the semiconductor layer 204 along a longitudinal direction (i.e., along the [110] crystallographic of the source feature 232S).

The semiconductor device 100a further includes a front contact 116a and a back contact 116b. The front contact 116a and the back contact 116b each include an electrically conducting material that is coupled to the source feature 232S. In this regard, each of the front contact 116a and the back contact 116b includes a contact epitaxial layer 118 that is formed in contact with the source feature 232S. According to various embodiments, the contact epitaxial layer 118 has a doping concentration greater than that of the source feature 232S. As such, the electrical conductivity of the contact epitaxial layer 118 is chosen to match more closely that of the electrically conducting material that forms the front contact 116a and the back contact 116b, thereby reducing electrical resistance associated with the front contact 116a and the back contact 116b. The gate structure 240 and the front contact 116a are formed within an interlayer dielectric (ILD) layer 236, as described in greater detail below. The semiconductor device 100a further includes a contact etch stop layer 234 formed between the ILD layer 236 and the source/drain features (232S, 232D), as described in greater detail below.

FIG. 1B is a vertical cross-sectional view of a portion of the front contact 116a and FIG. 1C is a vertical cross-sectional view of a portion of the back contact 116b, according to various embodiments. As shown in FIGS. 1A to 1C, a silicide layer 120 is formed between the front contact 116a and the contact epitaxial layer 118 and also between the back contact 116b and the respective contact epitaxial layer 118. According to various embodiments, the source feature 232S and the contact epitaxial layer 118 are formed of doped semiconductor materials (e.g., silicon, SiGe, etc.), and the electrically conducting material of the front contact 116a and the back contact 116b is metallic. As such, the silicide layer 120 is chosen to be a metal/semiconductor alloy such as TiSi. According to various embodiments, the contact epitaxial layer 118 has a thickness 122 that is between about 0.5 nm and about 10 nm, and the silicide layer 120 has a similar thickness.

According to various embodiments, the source feature 232S and the contact epitaxial layer 118 are each n-type doped semiconductor layers. For example, according to some embodiments, the source feature 232S is an n-type doped silicon layer and the contact epitaxial layer 118 is an n-type doped silicon layer formed over the source feature 232S. The contact epitaxial layer 118 is doped more heavily than the source feature 232S. For example, in some embodiments, the source feature 232S is doped with phosphorous having a dopant concentration that is between about 5×10²⁰ atom/cm³ and about 5×10²¹ atom/cm while the contact epitaxial layer 118 is doped with phosphorous having a dopant concentration that is between about 1×10²¹ atom/cm³ and about 7×10²¹ atom/cm³.

In other embodiments, the source feature 232S and the contact epitaxial layer 118 are each p-type doped semiconductor layers. For example, according to some embodiments, the source feature 232S is a first p-type doped SiGe alloy layer and the contact epitaxial layer 118 is a second p-type doped SiGe alloy layer formed over the source/drain epitaxial layer. In some embodiments, the source feature 232S is a SiGe alloy layer having a composition SiₓGe₁₋ₓ, where x is between about 0.4 and about 0.6 and the contact epitaxial layer 118 is a SiGe alloy layer having a composition SiₓGe₁₋ₓ, where x is between about 0.05 and about 0.5. The contact epitaxial layer 118 is doped more heavily than the source feature 232S. For example, in some embodiments, the source feature 232S is doped with boron having a dopant concentration that is between about 7×10²⁰ atom/cm³ and about 1×10²¹ atom/cm³ while the contact epitaxial layer 118 is doped with boron having a dopant concentration that is between about 1×10²⁰ atom/cm³ and about 7×10²¹ atom/cm³.

As shown in FIG. 1A, the semiconductor device 100a includes inner spacer features 220 formed between the gate dielectric layer 242 and the source feature 232S, and between the gate dielectric layer 242 and the drain features 232D. In some embodiments, the inner spacer features 220 are made of a dielectric material, such as a silicon-containing dielectric material, including but not limited to silicon oxide, silicon nitride, silicon carbide, silicon oxynitride, silicon carbon nitride, silicon oxy carbonitride, and/or oxygen-doped silicon carbonitride. In some embodiments, the inner spacer features 220 include a low dielectric constant (low-k) material. For example, in some embodiments, the dielectric constant (k) values of the inner spacer features 220 are lower than that of silicon oxide, such as below 4.2, equal to or lower than about 3.9, or within a range from about 3.5 to about 3.9.

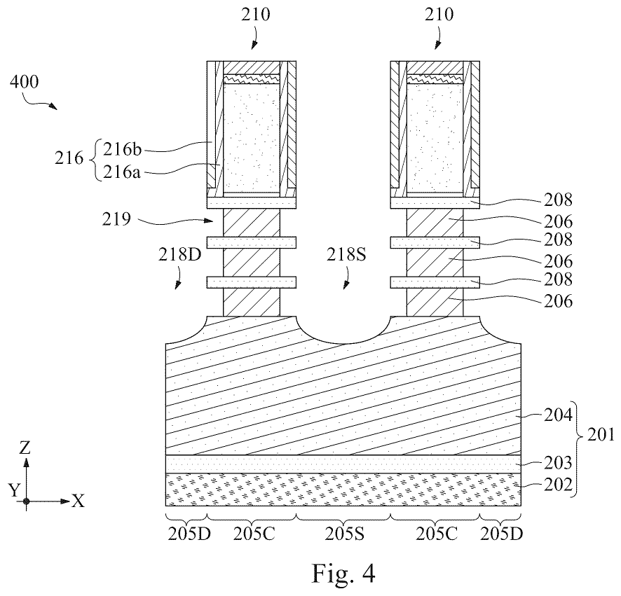

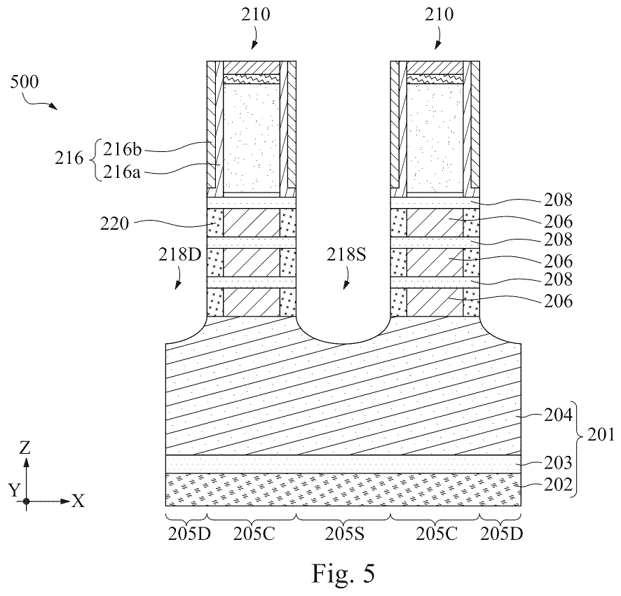

In some embodiments, the inner spacer features 220 are formed by a deposition process such as atomic layer deposition (ALD), chemical vapor deposition (CVD), such as plasma-enhanced chemical vapor deposition (PECVD), low-pressure chemical vapor deposition (LPCVD), or high aspect ratio process (HARP) CVD, another suitable technique, and/or a combination thereof. In some embodiments, an etching-back process is performed that includes an anisotropic etching process such as dry plasma etching, an isotropic etching process such as dry chemical etching, remote plasma etching, wet chemical etching, and/or a combination of these techniques, as described in greater detail with reference to FIGS. 4 and 5.

In embodiments where the semiconductor device 100a is formed as an n-channel nanostructure device, such as an n-channel GAA FET, source feature/drain features (232S, 232D), include semiconductor materials such as silicon phosphide (SiP), silicon arsenide (SiAs), silicon carbide phosphide (SiCP), silicon carbide (SiC), silicon, gallium arsenide (GaAs), or another suitable semiconductor material, or a combination thereof. In some embodiments, the source/drain features (232S, 232D) are doped with an n-type dopant during the epitaxial growth process. For example, in certain embodiments, the n-type dopant is phosphorus or arsenic. In some embodiments, the source/drain features (232S, 232D) are epitaxially grown silicon doped with phosphorus to form silicon phosphide (SiP).

In embodiments where the semiconductor device 100a is formed as a p-channel nanostructure device, such as a p-channel GAA FET, the source/drain features (232S, 232D) are made of semiconductor materials such as silicon germanium (SiGe), silicon (Si), gallium arsenide (GaAs), or another suitable semiconductor material, or a combination thereof. In some embodiments, the source/drain features (232S, 232D) are doped with a p-type dopant during the epitaxial growth process. For example, in certain embodiments, the p-type dopant is boron or boron difluoride (BF₂). In some embodiments, the source/drain features (232S, 232D) are epitaxially grown SiGe doped with boron to form SiGe source/drain features 106.

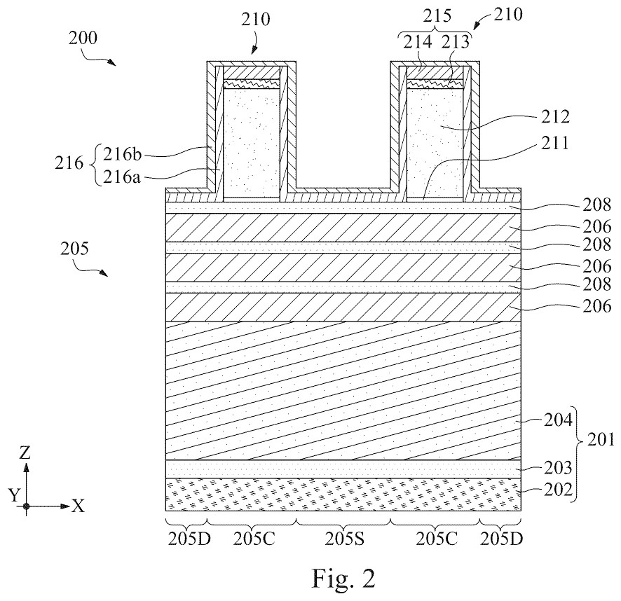

In some embodiments, the epitaxial growth process used to form the source feature 232S is cyclic deposition etch epitaxy (CDE). CDE involves periodic deposition operations, where the semiconductor structure is exposed to a pulse of precursors for deposition and doping, followed by exposure to an etchant gas for a first period. This is followed by a second period during which the semiconductor device is exposed only to the etchant gas, without precursors. The process then repeats, with a third period during which the semiconductor device is again exposed to the precursor pulse for deposition and doping, followed by the etchant gas. This cycle is repeated until the desired thickness of the source/drain features (232S, 232D) is formed. Further details of the processing operations used to form the semiconductor device 100a are described in greater detail with reference to FIGS. 2 to 10E, below.

FIG. 2 is a vertical cross-sectional view of a structure 200 that is used in the formation of a semiconductor device 100a, according to various embodiments. The structure 200 includes a substrate 201. In an embodiment, the substrate 201 is a bulk silicon substrate (i.e., including bulk single-crystalline silicon). The substrate 201 includes other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof, or other suitable materials. In some alternative embodiments, the substrate 201 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates are fabricated using separation by implantation of oxygen (SIMOX), wafer bonding, and/or other suitable methods. In the depicted embodiment, the substrate 201 is an SOI substrate and includes a carrier layer 202, an insulator layer 203 on the carrier layer 202, and a semiconductor layer 204 on the insulator layer 203. In some embodiments, the semiconductor layer 204 is silicon, silicon germanium, germanium, or other suitable materials and is undoped or unintentionally doped with a low dose of dopants. In the depicted example, the carrier layer 202 includes silicon, the insulator layer 203 includes silicon oxide, and the semiconductor layer 204 includes silicon (i.e., single-crystalline silicon).

The structure 200 includes a fin-shaped structure 205 disposed over the substrate 201. The fin-shaped structure 205 extends lengthwise along the X direction and is divided into channel regions 205C overlapped by sacrificial gate stacks 210 (as described below), source regions 205S, and drain regions 205D. In this example, two channel regions 205C, one source region 205S, and two drain regions 205D are shown in FIG. 2, but the structure 200 includes additional source/drain regions (205S, 205D) and channel regions 205C in other embodiments.

The fin-shaped structure 205 is formed from a portion of the semiconductor layer 204 and a vertical stack of alternating semiconductor layers (206, 208) using a combination of lithography and etch steps. An exemplary lithography process involves spin-on coating a photoresist layer, soft baking the photoresist layer, aligning a mask, exposing, post-exposure baking, developing the photoresist layer, rinsing, and drying (e.g., hard baking). In some instances, the patterning of the fin-shaped structure 205 uses double-patterning or multi-patterning processes to create patterns with pitches smaller than those otherwise obtainable using a single, direct photolithography process. The etching process includes dry etching, wet etching, and/or other suitable techniques.

In the depicted embodiment, the vertical stack of alternating semiconductor layers (206, 208) includes a plurality of channel layers 208 interleaved by a plurality of sacrificial layers 206. Each of the channel layers 208 consists of silicon (Si), and each of the sacrificial layers 206 consists of silicon germanium (SiGe). The channel layers 208 and the sacrificial layers 206 are epitaxially deposited on the substrate 201 using molecular beam epitaxy (MBE), vapor-phase epitaxy (VPE), ultra-high vacuum CVD (UHV-CVD), and/or other suitable epitaxial growth processes.

While not explicitly shown in FIG. 2, an isolation feature surrounds the fin-shaped structure 205 to isolate it from adjacent fin-shaped structures (i.e., that are separated from one another along the y direction). In some embodiments, the isolation feature is deposited in trenches that define the fin-shaped structure 205. These trenches extend through the channel layers 208 and sacrificial layers 206 and terminate in the substrate 201. The isolation feature also referred to as a shallow trench isolation (STI) feature, is formed using a dielectric material deposited over the structure 200 using techniques such as chemical vapor deposition (CVD), subatmospheric CVD (SACVD), flowable CVD (FCVD), physical vapor deposition (PVD), spin-on coating, and/or other suitable processes. The deposited dielectric material is planarized and recessed until the fin-shaped structure 205 rises above the isolation feature. The dielectric material for the isolation feature includes silicon oxide, silicon oxynitride, fluorine-doped silicate glass (FSG), a low-k dielectric, combinations thereof, and/or other suitable materials.

As mentioned above, the structure 200 includes sacrificial gate stacks 210 disposed over channel regions 205C of the fin-shaped structure 205. The channel regions 205C and the sacrificial gate stacks 210 define source regions 205S and drain regions 205D, which are regions that are not vertically overlapped by the sacrificial gate stacks 210. Each channel region 205C is positioned between a source region 205S and a drain region 205D along the X direction. FIG. 2 illustrates two sacrificial gate stacks 210, but other embodiments of the structure 200 include additional sacrificial gate stacks 210.

In this embodiment, a gate replacement process (or gate-last process) is adopted where the sacrificial gate stacks 210 serve as placeholders for functional gate structures (e.g., the gate structures 240 shown in FIG. 1A). The sacrificial gate stack 210 includes a sacrificial dielectric layer 211, a sacrificial gate electrode layer 212 over the sacrificial dielectric layer 211, and a gate-top hard mask layer 215 over the sacrificial gate electrode layer 212. The sacrificial dielectric layer 211 includes silicon oxide, the sacrificial gate electrode layer 212 is made of polysilicon, and the gate-top hard mask layer 215 is a multi-layer that includes a silicon oxide layer 213 and a silicon nitride layer 214 formed on the silicon oxide layer 213. Suitable deposition, photolithography, and etching processes are used to form the dummy gate stack 210.

As shown in FIG. 2, the structure 200 includes a gate spacer layer 216 disposed over the structure 200. The gate spacer layer 216 includes a first gate spacer layer 216a and a second gate spacer layer 216b deposited conformally over the structure 200, covering the top surfaces and sidewalls of the sacrificial gate stacks 210 and the top surfaces of the fin-shaped structure 205. The term “conformally” describes a layer with a substantially uniform thickness over various regions. A dielectric constant of the second gate spacer layer 216b exceeds that of the first gate spacer layer 216a, and the second gate spacer layer 216b exhibits greater etch resistance compared to the first gate spacer layer 216a in some embodiments. The first gate spacer layer 216a includes silicon oxide, silicon oxycarbide, or a suitable low-k dielectric material in some embodiments. The second gate spacer layer 216b includes silicon carbonitride, silicon nitride, zirconium oxide, aluminum oxide, or a suitable dielectric material in some embodiments. The first gate spacer layer 216a and the second gate spacer layer 216b are deposited over the dummy gate stacks 210 using processes such as CVD, SACVD, FCVD, atomic layer deposition (ALD), PVD, or other suitable processes.

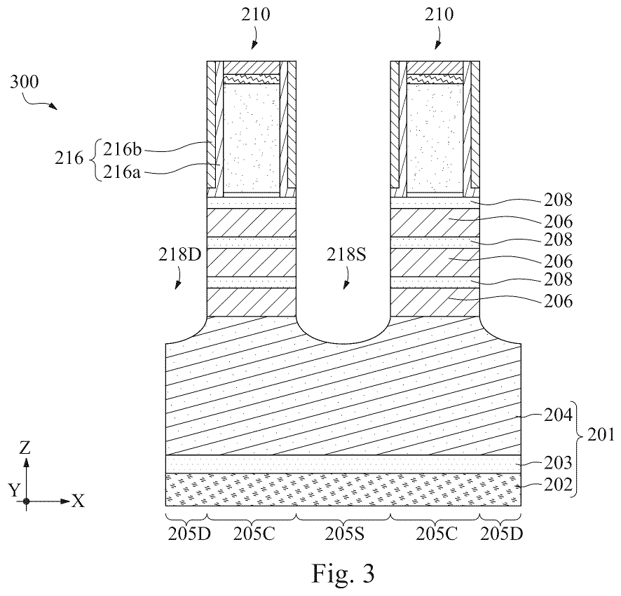

FIG. 3 is a vertical cross-sectional view of a structure 300 that is used in the formation of a semiconductor device 100a, according to various embodiments. The structure 300 is formed from the structure 200 by recessing a source region 218S and two drain regions 218D of the fin-shaped structure 205 to create a source opening and two drain openings, according to various embodiments. In some embodiments, the source region 218S and drain regions 218D of the fin-shaped structures not covered by the dummy gate stack and the gate spacer layer are anisotropically etched using a dry etching process or a suitable etching technique. A dry etching process utilizes oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, or combinations thereof. The source opening and drain openings extend through a vertical stack of channel layers 208 and sacrificial layers 206. These openings partially extend into the semiconductor layer 204 of the substrate 201. The sidewalls of the channel layers and the sacrificial layers are exposed within the source opening and drain openings, as shown in FIG. 3.

Referring to FIGS. 4 and 5, inner spacer features 220 are formed after the creation of the source opening 218S and the drain opening 218D. Once the source opening 218S and the drain opening 218D are formed, the sacrificial layers 206 are exposed within these openings. As shown in FIG. 4, the sacrificial layers 206 are selectively and partially recessed to create inner spacer recesses, while the exposed channel layers are not significantly etched. In an embodiment where the channel layers are made of silicon (Si) and the sacrificial layers 206 are made of silicon germanium (SiGe), the selective and partial recessing of the sacrificial layers 206 involves a selective isotropic etching process, which can include either a selective dry etching process or a selective wet etching process. The extent of recessing is controlled by the duration of the etching process. After forming the inner spacer recesses, an inner spacer material layer is deposited over the structure, including within the recesses. The inner spacer material layer includes silicon oxide, silicon nitride, silicon oxycarbide, silicon oxycarbonitride, silicon carbonitride, metal nitride, or another suitable dielectric material. The deposited inner spacer material layer is then etched back to remove excess material from the sidewalls of the channel layers, thereby forming the inner spacer features 220, as shown in FIG. 5. In some embodiments, the etch-back process is a dry etching process, similar to that used for forming the source opening 218S and the drain opening 218D.

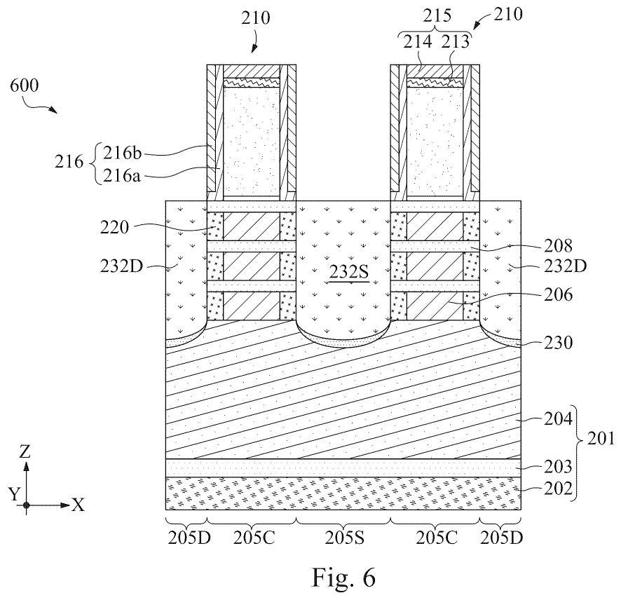

FIG. 6 is a vertical cross-sectional view of a structure 600 that is used in the formation of a semiconductor device 100a, according to various embodiments. As shown in FIG. 6, a source feature 232S is formed in the source opening 218S, and drain features 232D are formed in the drain opening 218D. Before the formation of the source feature 232S and the drain features 232D, an isolation structure 230 is formed at the bottom of the source opening 218S and the bottom of the drain opening 218D. The isolation structure 230 is a dielectric layer and is referred to as a “flexible bottom isolation” structure in some embodiments. The isolation structure 230 reduces or substantially prevents current leakage between the source feature 232S, the drain features 232D, and the semiconductor layer 204, or additional features to be formed at the backside of the structure 200. In some embodiments, the isolation structure 230 includes silicon oxide, silicon nitride, SiCN, SiCON, SiOC, SiC, or other suitable materials and is formed by oxidation (e.g., to form silicon oxide) or by a conformal deposition process followed by further processing, as follows.

The isolation structure 230 is formed by performing one or more conformal film deposition processes, such as plasma-enhanced atomic layer deposition (PEALD) or PECVD, followed by a film treatment process, such as etching back. The resulting conformal thin film inherits the shape of the underlying structure upon which it is formed. The film deposition process employs a cyclic PEALD method with reaction gases such as dichlorosilane (DCS) and ammonia/argon (NH₃/Ar) plasma. The subsequent film treatment process uses argon/nitrogen (Ar/N₂) plasma for etching.

In other embodiments, the isolation structure 230 is formed as an epitaxial semiconductor feature that is epitaxially and selectively formed over the exposed top surfaces of the semiconductor layer 204 using an epitaxial process, such as molecular beam epitaxy (MBE), vapor-phase epitaxy (VPE), ultrahigh-vacuum chemical vapor deposition (UHV-CVD), metal-organic chemical vapor deposition (MOCVD), or other suitable epitaxial growth processes. In such embodiments, the bottom surface of the isolation structure 230 generally follows the shape of the bottom surface of the source and drain openings (218S, 218D). Since the surfaces of the inner spacer features 220 are not conducive to epitaxial deposition, the isolation structure 230 forms in a bottom-up fashion from the exposed surface of the semiconductor layer 204 of the substrate 201. In cross-section, the isolation structure 230 exhibits a crescent shape in the illustrated embodiment. Depending on the conductivity type of the source feature 232S, the isolation structure 230 includes different compositions. For an n-type source feature 232S, the isolation structure 230 includes undoped silicon (Si), and for a p-type source feature 232S, the isolation structure 230 includes undoped silicon germanium (SiGe) in some embodiments.

In some embodiments, an additional isolation structure including a dielectric layer is formed on the epitaxial semiconductor feature. The isolation structure can be referred to a “flexible bottom isolation” structure. The source feature 232S and the drain feature 232D are formed over the isolation structure 230 using an epitaxial process, such as vapor-phase epitaxy (VPE), ultrahigh-vacuum chemical vapor deposition (UHV-CVD), molecular beam epitaxy (MBE), or other suitable processes. The epitaxial process uses gaseous and/or liquid precursors that interact with the composition of the isolation structure 230. The source feature 232S and the drain feature 232D are coupled to the channel layers 208 in the channel regions 205C of the fin-shaped structure 205. Depending on the conductivity type of the transistor being formed, the source feature 232S and the drain feature 232D are n-type and p-type source/drain features, respectively.

Exemplary n-type source/drain features include silicon, phosphorus-doped silicon, arsenic-doped silicon, antimony-doped silicon, or other suitable materials, and these may be in-situ doped during the epitaxial process by introducing an n-type dopant, such as phosphorus, arsenic, or antimony, or ex-situ doped using a ion implantation process. Exemplary p-type source/drain features include germanium, gallium-doped silicon germanium, boron-doped silicon germanium, or other suitable materials, and these may be in-situ doped during the epitaxial process by introducing a p-type dopant, such as boron or gallium, or ex-situ doped using a ion implantation process. In some embodiments, a lightly doped epitaxial semiconductor layer is formed between the source/drain feature (232S, 232D) and the corresponding isolation structure 230, and the doping concentration of the lightly doped epitaxial semiconductor layer is lower than the doping concentration of the source/drain feature (232S, 232D).

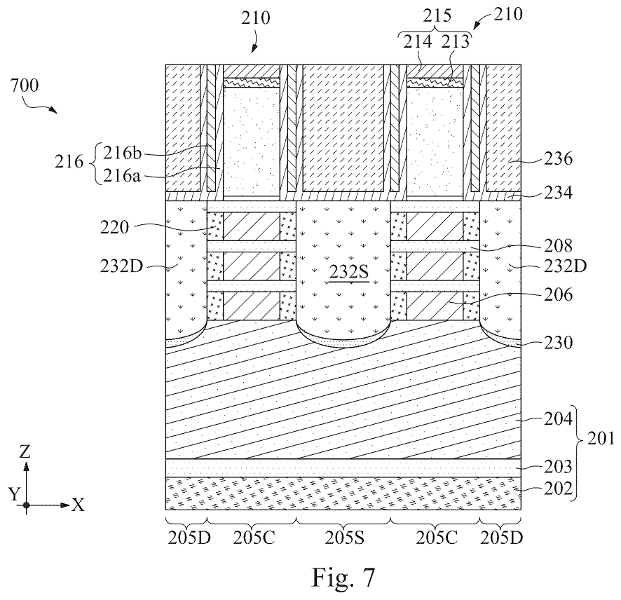

FIG. 7 is a structure formed from FIG. 6 and includes a contact etch stop layer (CESL) 234 and an interlayer dielectric (ILD) layer 236, according to various embodiments. The CESL 234 includes silicon nitride, silicon oxynitride, and/or similar materials and is formed by atomic layer deposition (ALD), plasma-enhanced chemical vapor deposition (PECVD), or other suitable deposition or oxidation processes. As shown in FIG. 7, the CESL 234 is deposited on top surfaces of the source feature 232S, the drain features 232D, and the sidewalls of the gate spacer layer 216. The ILD layer 236 is deposited by a PECVD process or another suitable deposition technique over the CESL 234. The ILD layer 236 is made from materials such as tetraethylorthosilicate (TEOS) oxide, undoped silicate glass, or doped silicon oxide, such as borophosphosilicate glass (BPSG), fused silica glass (FSG), phosphosilicate glass (PSG), boron-doped silicon glass (BSG), and/or other suitable dielectric materials. In some embodiments, after forming the ILD layer 236, the structure 200 is annealed to improve the integrity of the ILD layer 236.

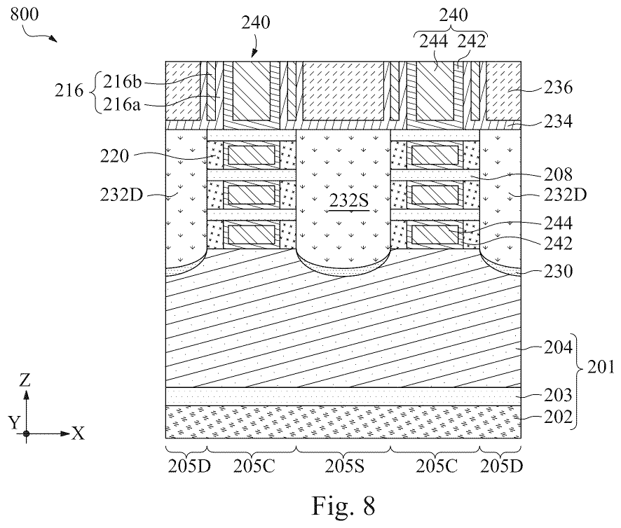

FIG. 8 is a structure 800 formed from the structure 700 of FIG. 7, according to various embodiments. The structure 800 is formed by replacement of the sacrificial gate stacks 210 with the gate structures 240, according to various embodiments. A planarization process, such as a chemical mechanical polishing (CMP) process, is performed on the structure 700 to remove excessive materials and expose the top surfaces of the sacrificial gate electrode layer 212 in the sacrificial gate stacks 210. After the exposure of the sacrificial gate electrode layer 212, the next step is the removal of the sacrificial gate stacks 210 of the structure 700. The removal of the sacrificial gate stacks 210 includes one or more etching processes selective to the material in the sacrificial gate stacks 210. For example, the removal of the sacrificial gate stacks 210 is performed using a selective wet etch, a selective dry etch, or a combination thereof. After removing the sacrificial gate stacks 210, the sacrificial layers 206 are selectively removed to release the channel layers 208 in the channel regions 205C. The selective removal of the sacrificial layers 206 is implemented by a selective dry etch, a selective wet etch, or another selective etching process. In some embodiments, the selective wet etching includes an APM etch (e.g., an ammonia hydroxide-hydrogen peroxide-water mixture).

Each of the gate structures 240 includes a gate dielectric layer 242 and a gate electrode layer 244 over the gate dielectric layer 242. In some embodiments, the gate dielectric layer 242 includes an interfacial layer disposed on the channel layers 208 and a high-k dielectric layer over the interfacial layer. A high-k dielectric layer refers to a dielectric material with a dielectric constant greater than that of silicon dioxide, which is about 3.9. A low-k dielectric layer refers to a dielectric material with a dielectric constant no greater than that of silicon dioxide. In some embodiments, the interfacial layer includes silicon oxide. The high-k dielectric layer is then deposited over the interfacial layer using ALD, CVD, or other suitable methods. According to various embodiments, the high-k dielectric layer includes hafnium oxide. Alternatively, according to various embodiments, the high-k dielectric layer includes other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO3, BaTiO₃, BaZrO₃, hafnium lanthanum oxide, lanthanum silicon oxide, aluminum silicon oxide, hafnium tantalum oxide, hafnium titanium oxide, (Ba, Sr)Ti₃ (BST), silicon nitride, silicon oxynitride, combinations thereof, or other suitable materials.

The gate electrode layer 244 is deposited over the gate dielectric layer 242 using ALD, PVD, CVD, e-beam evaporation, plating, or other suitable methods. The gate electrode layer 244 includes either a single layer or a multi-layer structure, such as various combinations of a metal layer with a selected work function to enhance device performance (work function metal layer), a liner layer, a wetting layer, an adhesion layer, a metal alloy, or a metal silicide. By way of example, the gate electrode layer 244 includes titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or combinations thereof. Further, in embodiments in which the structure 800 includes n-type and p-type transistors, different gate electrode layers are formed separately for the n-type and p-type transistors, with each layer including different work function metal layers (e.g., to provide different n-type and p-type work function metal layers).

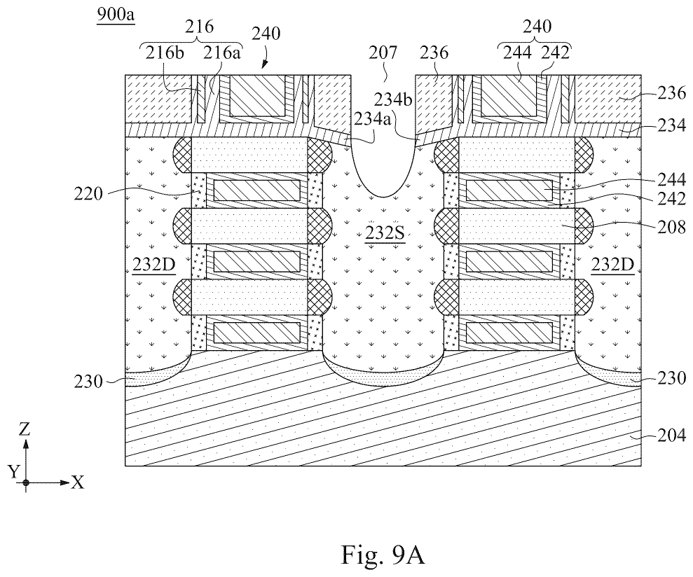

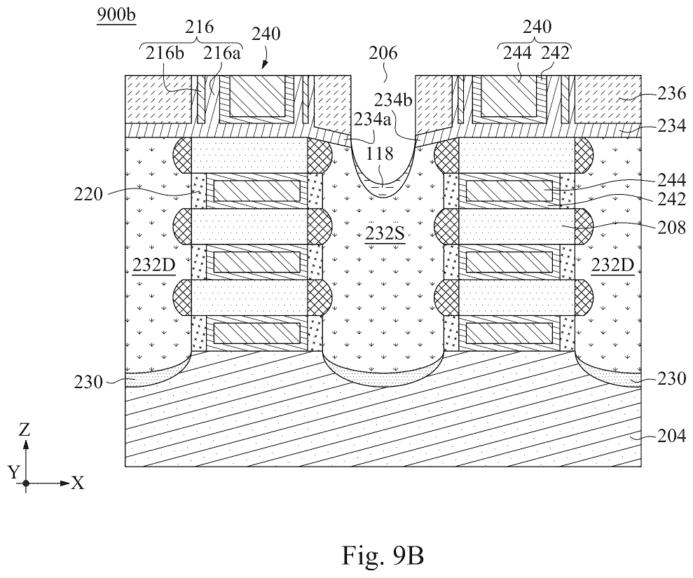

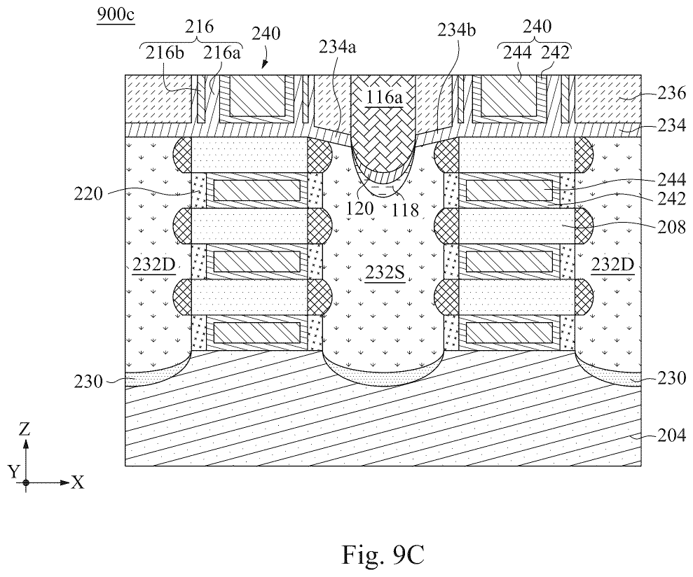

FIGS. 9A to 9C are vertical cross-sectional views of structures (900a, 900b, 900c) that are used in the formation of a front contact 116a in a semiconductor device 100a, according to various embodiments. As shown in FIG. 9A, a portion of the ILD layer 236 is etched to form an opening 207. The etching process is allowed to progress such that a portion of the source feature 232S is also removed. Further, the etching process removes a portion of the CESL 234 such that the CESL 234 is divided into a first CESL portion 234a and a second CESL portion 234b. In this embodiment, the first CESL portion 234a and the second CESL portion 234b are configured to be angled relative to the horizontal direction (i.e., the X direction). This configuration illustrates that, according to various embodiments, the CESL 234 need not have a horizontal orientation in situations in which a top surface of the source feature 232S does not have a horizontal surface. For example, in some embodiments, the source feature 232S has angled facets, and in such embodiments, the CESL 234 conforms to the angled facets and therefore has an angled configuration. Thus, upon etching, the angle configuration of the CESL 234 gives rise to the angled first CESL portion 234a and the second CESL portion 234b, as shown in FIG. 9A.

After formation of the opening 207, the contact epitaxial layer 118 is then formed over the source feature 232S by performing a deposition process (e.g., a MOCVD deposition process) in some embodiments, as illustrated in FIG. 9B. For example, in certain embodiments, forming the source feature 232S further includes depositing a first layer of n-type doped silicon and forming the contact epitaxial layer 188 further includes depositing a second layer of n-type doped silicon over the first epitaxial layer 232S. According to such embodiments, the deposition process is performed to provide in-situ doping of the source feature 232S and the contact epitaxial layer 118 such that the source feature 232S has a first concentration of phosphorous that is between about 5×10²⁰ atom/cm³ and about 5×10²¹ atom/cm³ and the contact epitaxial layer 118 has a second concentration of phosphorus that is between about 1×10²¹ atom/cm³ and about 7×10²¹ atom/cm³.

Alternatively, in other embodiments, forming the source feature 232S further includes depositing a first p-type doped SiGe alloy layer and forming the contact epitaxial layer 118 further includes depositing a second p-type doped SiGe alloy layer over the source feature 232S. For example, in certain embodiments, the source feature 232S includes SiₓGe₁₋ₓ, where x is between 0.4 and 0.6 and the contact epitaxial layer 118 includes SiₓGe₁₋ₓ, where x is between 0.05 and 0.5. According to such embodiments, the deposition process is performed to provide in-situ doping of the source feature 232S and the contact epitaxial layer 118 such that the source feature 232S has a first concentration of boron that is between about 7×10²⁰ atom/cm³ and about 1×10²¹ atom/cm³ and the contact epitaxial layer 118 has a second concentration of boron that is between about 1×10²⁰ atom/cm³ and about 7×10²¹ atom/cm³.

The silicide layer 120 (e.g., see FIG. 9C) is then formed over the contact epitaxial layer 118 in some embodiments as follows. A thin layer of a metal (not shown), such as titanium, tantalum, cobalt, tungsten, or nickel, is deposited onto the source/drain epitaxial layers and the surrounding areas. This metal layer is then subjected to a rapid thermal annealing process, during which it reacts with the underlying silicon or SiGe layer to form a silicide layer. The choice of metal and the annealing conditions are controlled to optimize the formation of the desired silicide phase, such as titanium silicide, cobalt silicide, or nickel silicide, which exhibits lower resistivity than the source/drain features and stable electrical characteristics. After the formation of the silicide layer 120, any unreacted metal and metal silicide is removed from non-relevant areas in some embodiments, for example, by a selective etching process. This results in a highly conductive silicide layer 120 directly in contact with the contact epitaxial layer 118. The presence of the silicide layer 120 provides a highly conductive contact with the front contact 116a that is subsequently formed. Alternatively, in some embodiments, the selective etching process is omitted and a thin layer of the metal is left on exposed surfaces of the ILD layer 236 (not shown) before the formation of the front contact 116a.

The front contact 116a is then formed by deposing a conductive material over the silicide layer 120 within the opening 207. According to various embodiments, the conductive material is a combination of a metallic liner layer (such as a metallic nitride or a metallic carbide) and a metallic fill material. Each metallic liner layer includes one or more TiN, TaN, WN, TiC, TaC, or WC, and each metallic fill material portion includes W, Cu, Al, Co, Ru, Mo, Ta, Ti, alloys thereof, and/or combinations thereof. Other suitable metallic liner and metallic fill materials are within the contemplated scope of this disclosure and may also be used.

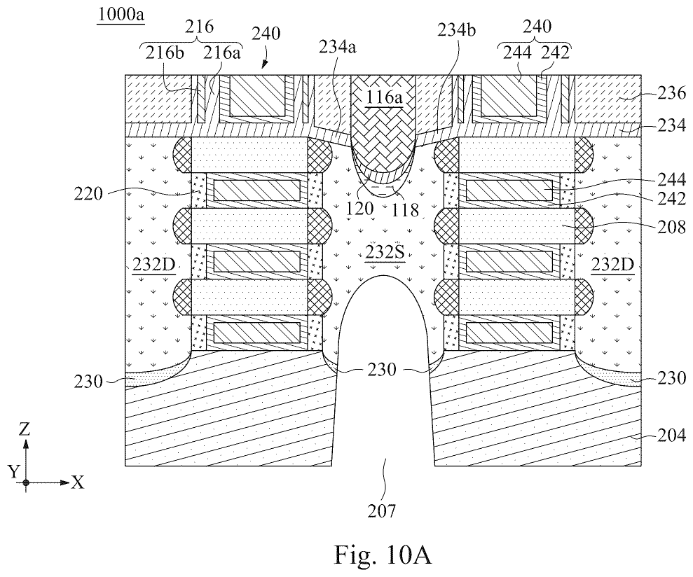

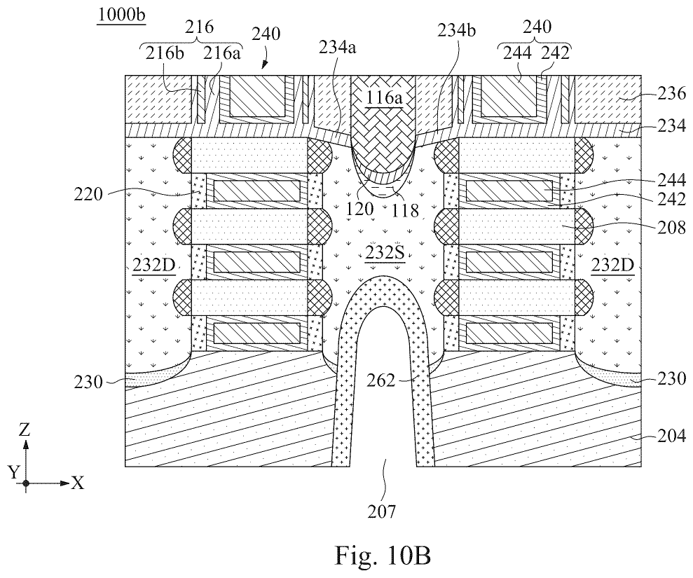

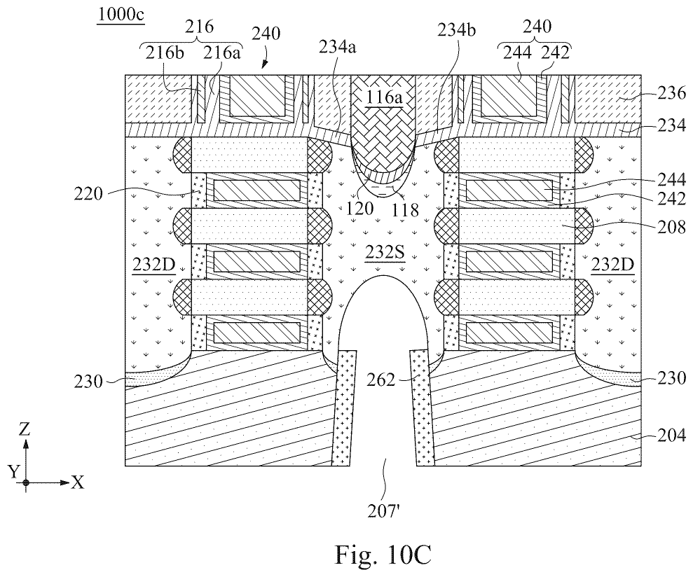

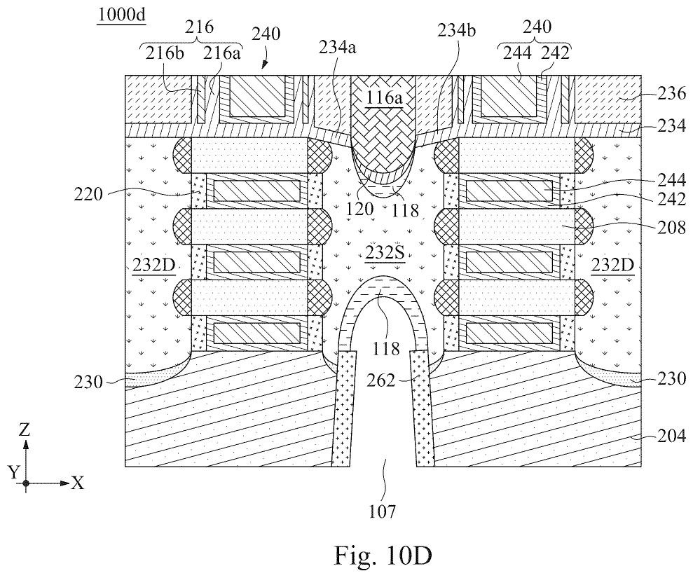

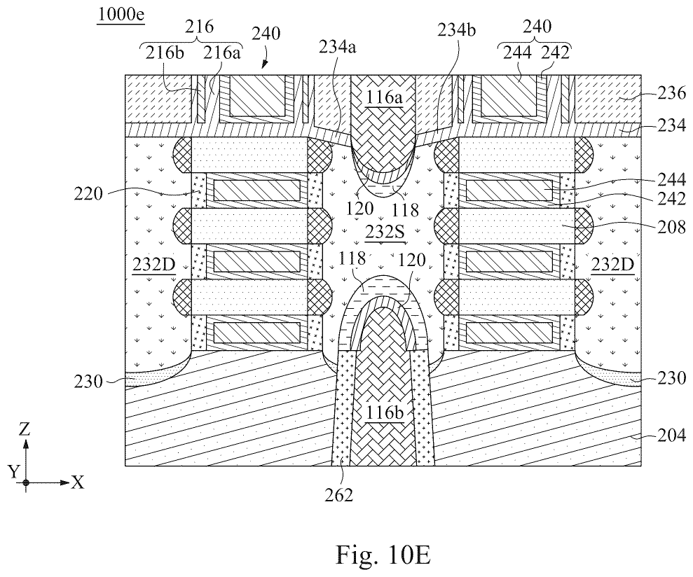

FIGS. 10A to 10E are vertical cross-sectional views of structures (1000a, 1000b, 1000c, 1000d, 1000e) that are used in the formation of a back contact 116b in a semiconductor device 100a, according to various embodiments. The processing operations that are illustrated in FIGS. 10A to 10E are similar to those of FIGS. 9A to 9C in forming the front contact 116a. As shown in FIG. 10A, the semiconductor layer 204 is patterned and etched to form an opening 207. As described above with reference to FIGS. 9A to 9C, the etching process is allowed to progress such that a backside portion of the source feature 232S is removed.

As shown in in FIG. 10A, a portion of the isolation structure 230 remains after the formation of the opening 207. As described above, the isolation structure 230 is configured to reduce or prevent leakage currents. As shown in FIG. 10B, after the formation of the backside source contact opening 207, in some embodiments, a dielectric barrier layer 262 is deposited over the structure 1000a. As shown in FIG. 10C, the dielectric barrier layer 262 is then etched back to cover only the sidewalls of the backside source contact opening 207 and to expose the source feature 232S. The backside source contact opening 207, partially covered by the dielectric barrier layer 262, is referred to as backside source contact opening 207′. In some embodiments, the dielectric barrier layer 262 includes silicon nitride or other suitable materials. The contact epitaxial layer 118 is then deposited over the source feature 232S using a conformal deposition process (e.g., MOCVD), as described above, and as illustrated in FIG. 10D. The silicide layer 120 and the back contact 116b are then formed over the contact epitaxial layer 118, as described above with reference to FIGS. 9A to 9C, and as illustrated in FIG. 10E. FIGS. 9A to 10E show contacts (116a, 116b) formed in the source feature 232S. In further embodiments (not shown), similar processes are performed to form contacts in the drain features 232D.

FIGS. 10F to 10H are vertical cross-sectional views of structures (1000f, 1000g, 1000h) having alternative configurations for the back contact 116b and related structures (118, 120). For example, as shown in FIG. 10F, the contact epitaxial layer 118 and the silicide layer 120 have a curved shape, each with a smallest width W_1 which is between about 1 nm and about 10 nm, and a bottom width W_B which is between about 5 nm and about 15 nm. A height H of the contact structure below a surface of the gate structure 240 is between about 50 nm and about 100 nm. In further embodiments, the contact epitaxial layer 118 and the silicide layer 120 are configured in other shapes, such as a triangular shape as shown in FIG. 10G, a diamond shape (having corresponding height H and widths W_1 and W_2), as shown in FIG. 10H, etc.

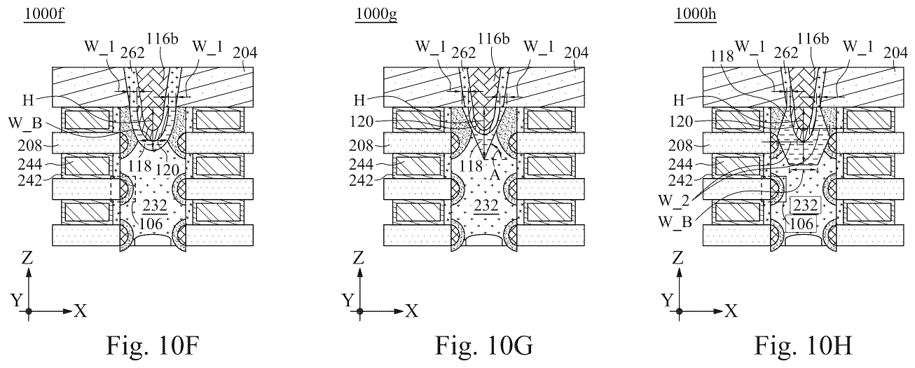

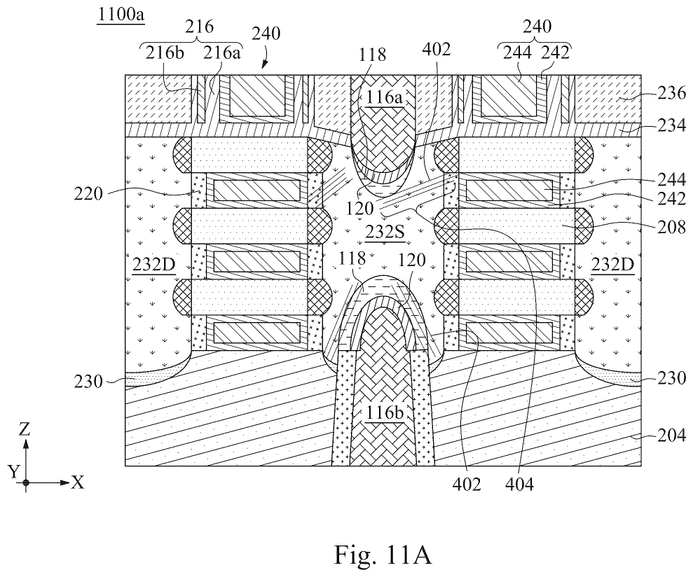

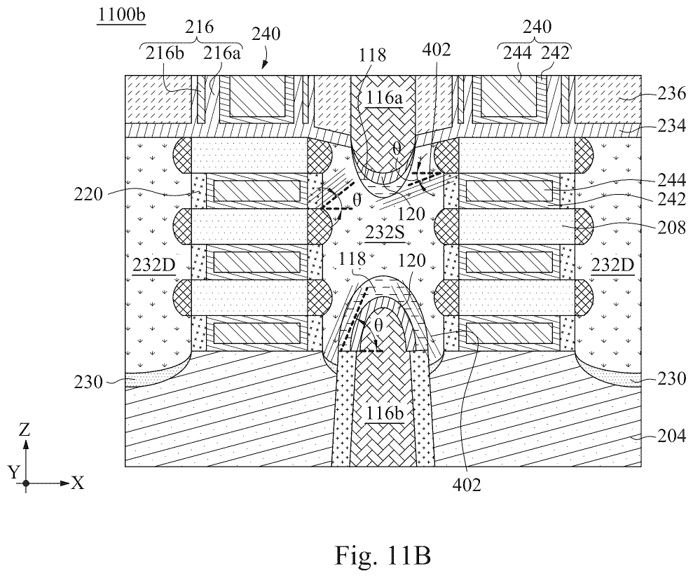

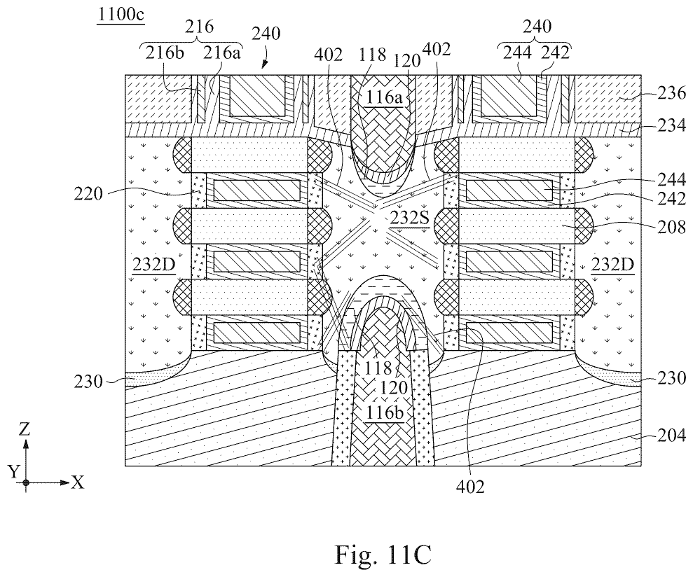

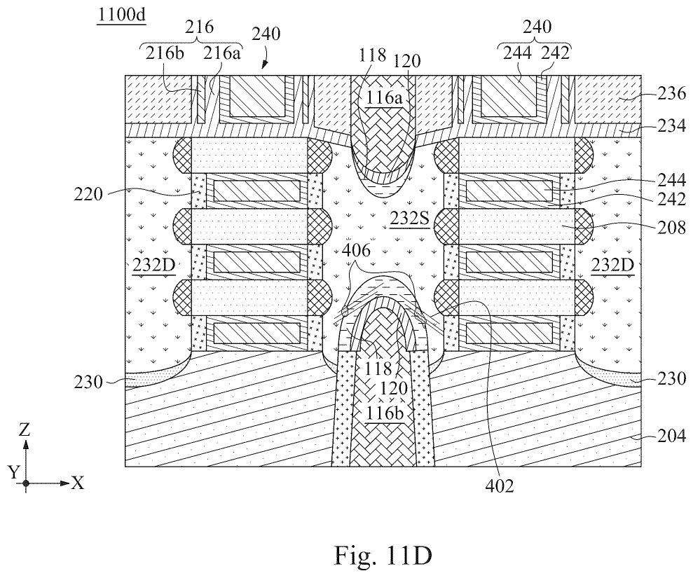

FIGS. 11A to 11D are vertical cross-sectional views of semiconductor device structures (1100a, 1100b, 1100c, 1100d) having various defects, according to various embodiments. As shown in FIGS. 11A to 11C, the source feature 232S and the contact epitaxial layer 118 include crystalline material having dislocations 402. The dislocations 402 are generated due to lattice constant mismatch between differing materials such as between the material of the source feature 232S and the material of the inner spacer features 220 and/or between the source feature 232S and the dielectric barrier layer 262.

The formation of dislocations 402 in the source feature 232S presents both advantages and disadvantages that can impact the performance and reliability of the semiconductor device 100a. One advantage of dislocations 402, for example in strained layers like silicon-germanium (SiGe) for the source feature 232S, is that such dislocations 402 can relax strain in the material, which helps prevent excessive stress that could otherwise lead to defects or device failure. In some cases, controlled dislocation formation can be used to relieve strain without affecting the overall device performance, particularly in heterostructures where strain engineering is critical for enhancing carrier mobility in the transistor channel.

However, the disadvantages of dislocations 402 can be more pronounced in some embodiments. In the source feature 232S, dislocations 402 can create pathways for leakage currents, which degrade the device's electrical performance by increasing off-state current and reducing the effectiveness of the semiconductor device 100a. These defects can also interfere with charge carrier mobility, leading to reduced drive currents and slower switching speeds. In contact epitaxial layers 118, dislocations 402 at the metal-semiconductor interface can increase contact resistance, which can hinder current flow between the metal and the semiconductor. This can degrade device performance, especially in advanced transistor designs where low contact resistance is desirable for maintaining high efficiency and low power consumption. Furthermore, dislocations 402 can serve as recombination centers for charge carriers, reducing the efficiency of devices like photodetectors and LEDs.

Overall, while dislocations 402 may offer some strain relief benefits, their presence poses challenges in terms of increased leakage, reduced carrier mobility, and higher contact resistance, which can negatively affect both the performance and longevity of semiconductor devices. Therefore, minimizing dislocations 402 through careful epitaxial growth processes and strain management is advantageous for ensuring optimal device function.

According to certain embodiments, high-quality devices (i.e., with a low density of dislocations 402) are generated using a deposition process in which the source feature 232S is formed at a first temperature and the contact epitaxial layer 118 is formed at a second temperature that is about 20% to about 30% lower than the first temperature, using precursor gas compositions and pressures as described above. For example, using high-order Si and Ge precursors (i.e., chain molecules having multiple Si or Ge atoms bonded to hydrogen atoms) along with the above-described temperature ranges allows achieving hole active concentrations as high as 1.3×10²¹ cm⁻³, for example, in in-situ B-doped Si_{0.5}Ge_{0.5}, providing Ti/SiGe: B contacts with low specific resistivity. For example, while higher processing temperatures (e.g., 600° C. to 700° C.) lead to a relatively high resistivity (e.g., 0.55 mohm·cm), lower processing temperatures (e.g., 500° C., 475° C., and 450° C.) lead to correspondingly lower resistivities (e.g., 0.31 mohm·cm, 0.27 mohm·cm, and 0.21 mohm·com). Such results are obtained using, for example, precursor gases including Si₂H₆, Ge₂H₆, or Cl₂.

According to certain embodiments, semiconductor device structures (1100a, 1100b, 1100 c, 1100 d) are formed with 50 or fewer dislocations 402 and individual dislocations 402 having dislocation lengths 404 (see FIG. 11A) that are between about 1 nm and about 40 nm. Further, according to certain embodiments, it may be advantageous to have dislocation angles θ that are not aligned with crystallographic directions. For example, as shown in FIG. 11B, in certain embodiments, dislocations 402 are formed that subtend an angle θ that is between about 20 degrees and about 70 degrees relative to a [110] crystallographic plane. Such dislocations 402 may operate to reduce strain while not significantly increasing resistance or allowing leakage currents. As shown in FIG. 11C, dislocations 402 can form at various interfaces between the source/drain features (232S, 232D), the inner spacer features 220, the contact epitaxial layer 118, etc.

As shown in FIG. 11D, another type of defect includes dopant precipitates 406. The presence of dopant precipitates 406 may increase resistivity by rendering clusters of dopants electrically inactive. Such precipitates 406 also tend to act as nucleation centers for dislocations 402. As such, various embodiments include controlling the process conditions to reduce or eliminate dopant precipitates 406.

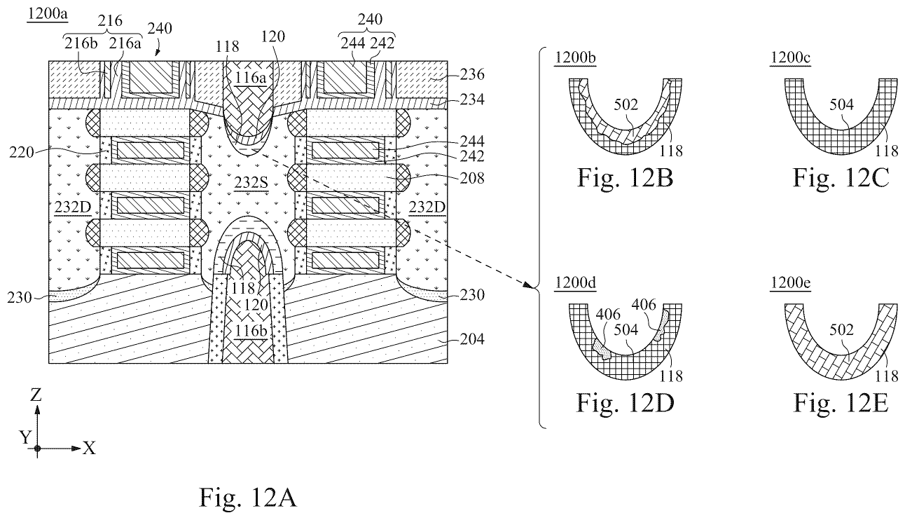

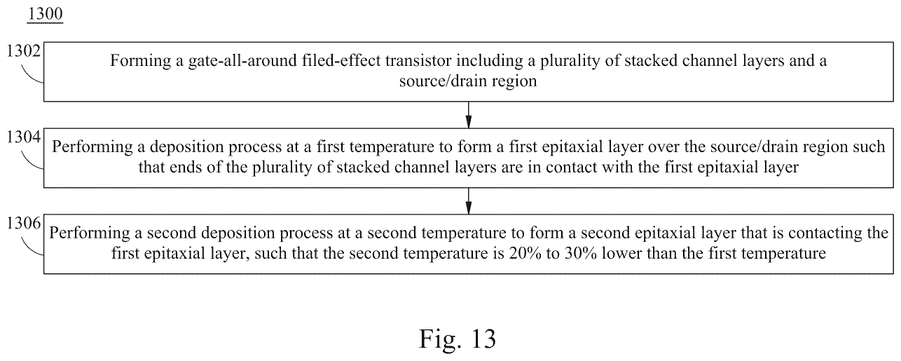

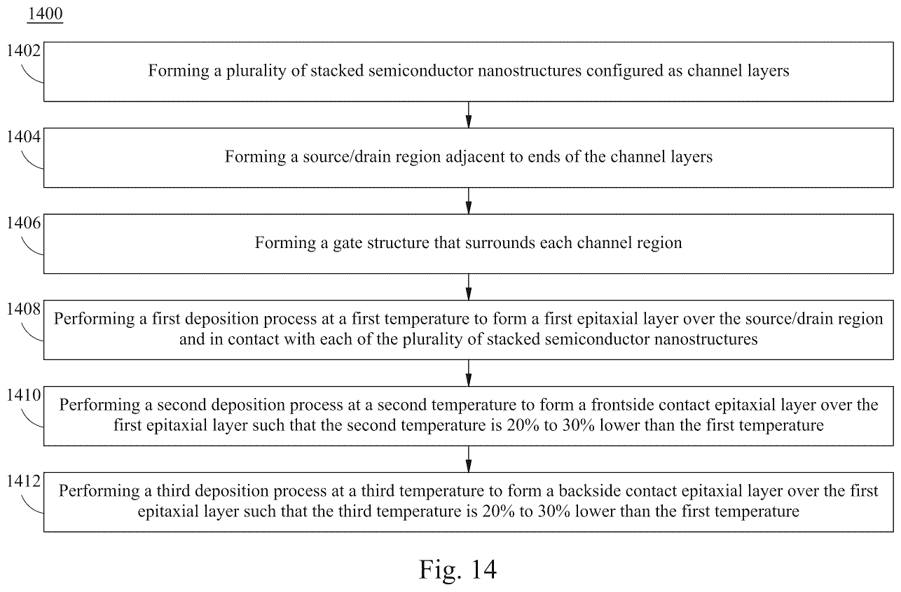

FIG. 12A is a vertical cross-sectional view of a semiconductor device structure 1200a having dopant precipitates 406 and/or amorphous regions 502, and FIGS. 12B to 12E are vertical cross-sectional views of contact epitaxial layers 118 having amorphous structures 502 (e.g., FIGS. 12B and 12E), crystalline structures 504 (e.g., FIGS. 12B, 12C, and 12D), and dopant precipitates 406 (e.g., FIG. 12D), according to various embodiments. As in the case of the dislocations 402, the presence of amorphous structures 502 (e.g., 12B and 12E) provides certain advantages in terms of reducing crystal strain. However, amorphous structures 502 have the disadvantage of increased resistivity due to a reduction in and density of activated dopants. As shown in FIG. 12D, dopant precipitates 406 act as nucleation sites for the growth of amorphous structures 502, as well as being centers for the generation of dislocations 402 (e.g., see FIG. 11D). Various methods are provided for increasing device quality in terms of increased active dopant concentrations and reduced densities of dislocations 402, dopant precipitates 406, and amorphous structures 502, to thereby generate high-quality contact epitaxial layers 118 having predominantly crystalline structures 504, as described with reference to FIGS. 13 and 14 below.

FIG. 13 is a flowchart illustrating operations of a method 1300 of forming a semiconductor device 100a, according to various embodiments. In operation 1302, the method 1300 includes forming a gate-all-around field-effect transistor including a plurality of stacked channel layers 208 and a source/drain region (218S, 218D). In operation 1304, the method 1300 includes performing a deposition process at a first temperature to form a first epitaxial layer (232S, 232D) over the source/drain region (218S, 218D) such that ends of the plurality of stacked channel layers 208 are in contact with the first epitaxial layer (232S, 232D). In operation 1306, the method 1300 includes performing a second deposition process at a second temperature to form a second epitaxial layer 118 that contacts the first epitaxial layer (232S, 232D). According to various embodiments, the method 1300 is performed such that the second temperature is 20% to 30% lower than the first temperature.

According to various embodiments, the first epitaxial layer (232S, 232D) includes a first dopant concentration, the second epitaxial layer 118 includes a second dopant concentration that is greater than the first dopant concentration, and the second epitaxial layer 118 is formed after the first epitaxial layer (232S, 232D). According to various embodiments, in forming the first epitaxial layer (232S, 232D) according to operation 1304, the method 130 further includes depositing a first layer of n-type doped silicon, and in forming the second epitaxial layer 118 according to operation 1306, the method 1300 further includes depositing a second layer of n-type doped silicon over the first epitaxial layer (232S, 232D). According to various embodiments, the first epitaxial layer (232S, 232D) includes SiₓGe₁₋ₓ, where x is between about 0.4 and about 0.6. According to various embodiments, the first epitaxial layer (232S, 232D) further includes a first concentration of phosphorous that is between about 5×10²⁰ atom/cm³ and about 5×10²¹ atom/cm³, and the second epitaxial layer 118 further includes a second concentration of phosphorus that is between about 1×10²¹ atom/cm³ and about 7×10²¹ atom/cm³.

According to various embodiments, in depositing the first epitaxial layer (232S, 232D) according to operation 1304, the method 1300 further includes performing a first metal-organic chemical-vapor deposition (MOCVD) process using a first mixture of SiH₄, H₂SiCl₂, HCl, or GeH₄ precursor gases. In depositing the second epitaxial layer 118 according to operation 1306, the method 1300 further includes performing a second MOCVD deposition process using a second mixture of SiH₄, Si₂H₆, Si₃H₈, H₂SiCl₂, HCl, or Cl₂ precursor gases. According to various embodiments, depositing the first epitaxial layer (232S, 232D) further includes performing the first MOCVD deposition process such that the first temperature is between about 500° C. and about 850° C., and depositing the second epitaxial layer 118 further includes performing the second MOCVD deposition process such that the second temperature is between about 350° C. and about 680° C.

According to various embodiments, in forming the first epitaxial layer (232S, 232D) according to operation 1304, the method 1300 further includes depositing a first p-type doped SiGe alloy layer. In forming the second epitaxial layer 118 according to operation 1306, the method 1300 further includes depositing a second p-type doped SiGe alloy layer over the first epitaxial layer (232S, 232D). According to various embodiments, the first epitaxial layer (232S, 232D) includes SiₓGe₁₋ₓ, where x is between about 0.4 and about 0.6 and the second epitaxial layer 118 includes SiₓGe₁₋ₓ, where x is between about 0.05 and about 0.5. According to various embodiments, the first epitaxial layer (232S, 232D) includes a first concentration of boron that is between about 7×10²⁰ atom/cm³ and about 1×10²¹ atom/cm³, and the second epitaxial layer 118 includes a second concentration of boron that is between about 1×10²⁰ atom/cm³ and about 7×10²¹ atom/cm³.

According to various embodiments, in depositing the first epitaxial layer (232S, 232D) according to operation 1304, the method 1300 further includes performing a first MOCVD deposition process using a first mixture of SiH₄, H₂SiCl₂, HCl, or GeH₄ precursor gases. In depositing the second epitaxial layer 118 according to operation 1306, the method 1300 further includes performing a second MOCVD deposition process using a second mixture of SiH₄, Si₂H₆, Si₃H₈, H₂SiCl₂, HCl, Cl₂, GeH₄, or Ge₂H₆ precursor gases. According to various embodiments, in depositing the first epitaxial layer (232S, 232D) according to operation 1304, the method 1300 further includes performing the first MOCVD deposition process such that the first temperature is between about 500° C. and about 850° C. In depositing the second epitaxial layer 118 according to operation 1304, the method 1300 further includes performing the second MOCVD deposition process such that the second temperature is between about 320° C. and about 680° C.

FIG. 14 is a flowchart illustrating operations of a method 1400 of forming a semiconductor device 100a, according to various embodiments. In operation 1402, the method 1400 includes forming a plurality of stacked semiconductor nanostructures configured as channel layers 208. In operation 1404, the method 1400 includes forming a source/drain region (218S, 218D) adjacent to ends of the channel layers 208. In operation 1406, the method 1400 includes forming a gate structure 240 that surrounds each channel layer 208. In operation 1408, the method 1400 includes performing a first deposition process at a first temperature to form a first epitaxial layer (232S, 232D) over the source/drain region (218S, 218D) and in contact with each of the plurality of stacked semiconductor nanostructures 208. In operation 1410, the method 1400 includes performing a second deposition process at a second temperature to form a frontside contact epitaxial layer 118 over the first epitaxial layer (232S, 232D) such that the second temperature is about 20% to about 30% lower than the first temperature. In operation 1412, the method 1400 includes performing a third deposition process at a third temperature to form a backside contact epitaxial layer 118 over the first epitaxial layer (232S, 232D) such that the third temperature is about 20% to about 30% lower than the first temperature.

According to various embodiments, the first epitaxial layer (232S, 232D) includes a first dopant concentration, the frontside contact epitaxial layer 118 and the backside contact epitaxial layer 118 each include a second dopant concentration that is greater than the first dopant concentration, and the frontside contact epitaxial layer 118 is formed after the first epitaxial layer (232S, 232D) and the backside contact epitaxial layer 118 is formed after the frontside contact epitaxial layer 118. According to various embodiments, the first epitaxial layer (232S, 232D) includes a first n-type doped silicon layer including a first concentration of phosphorous that is between about 5×10²⁰ atom/cm³ and about 5×10²¹ atom/cm³ and the frontside contact epitaxial layer 118 and the backside contact epitaxial layer 118 each include a second n-type doped silicon layer including a second concentration of phosphorous that is between about 1×10²¹ atom/cm³ and about 7×10²¹ atom/cm³.

According to various embodiments, the first epitaxial layer (232S, 232D) includes SiₓGe₁₋ₓ, where x is between about 0.4 and about 0.6 and a first concentration of boron that is between about 7×10²⁰ atom/cm³ and about 1×10²¹ atom/cm³ and the frontside contact epitaxial layer 118 and the backside contact epitaxial layer 118 each include SiₓGe₁₋ₓ, where x is between about 0.05 and about 0.5 and a second concentration of boron that is between about 1×10²⁰ atom/cm³ and about 7×10²¹ atom/cm³. According to various embodiments, in depositing the first epitaxial layer (232S, 232D) according to operation 1408, the method 1400 further includes performing the first deposition process such that the first temperature is between about 500° C. and about 850° C. According to various embodiments, in depositing the frontside contact epitaxial layer 118 according to operation 1410, and in depositing the backside contact epitaxial layer 118 according to operation 1412, the method 1400 further includes performing the second deposition process and the third deposition process such that the second temperature and the third temperature are each between about 350° C. and about 680° C.

According to various embodiments, the method 1400 further includes forming a front contact 116a, forming a back contact 116b, and forming a silicide layer 120 between at least one of the frontside contact epitaxial layer 118 and the front contact 116a or between the backside contact epitaxial layer 118 and the back contact 116b, such that the silicide layer 120 includes a thickness that is less than about 10 nm.

Referring to all drawings and according to various embodiments of the present disclosure, a semiconductor device 100a is provided. The semiconductor device 100a includes a transistor structure 100a including a channel layer 208 and a source/drain region (218S, 218D), a first epitaxial layer (232S, 232D) formed over the source/drain region (218S, 218D) such that the first epitaxial layer (232S, 232D) is in contact with the channel layer 208, a second epitaxial layer 118 that is in contact with the first epitaxial layer (232S, 232D), and an electrically conductive contact (116a, 116b) connected to the second epitaxial layer 118 such that the second epitaxial layer 118 is between the second epitaxial layer 118 and the electrically conductive contact (116a, 116b).

According to various embodiments, the first epitaxial layer (232S, 232D) includes a crystalline structure with a first dopant concentration that is between about 5×10²⁰ atom/cm³ and about 5×10²¹ atom/cm³, and the second epitaxial layer 118 includes a crystalline structure with a second dopant concentration that is greater than the first dopant concentration and is between about 1×10²⁰ atom/cm³ and about 7×10²¹ atom/cm³, such that the second epitaxial layer 118 includes fewer than 50 dislocations. According to various embodiments, the second epitaxial layer 118 is substantially free of dopant precipitates 406. In this regard, “substantially free” means that any precipitates that are present are smaller than the size resolution (i.e., about 1 nm to about 2 nm) of transmission electron microscopy (TEM). According to various embodiments, the semiconductor device 100a further includes dislocations extending within the first epitaxial layer (232S, 232D) and the second epitaxial layer 118 having a length that is between about 1 nm and about 40 nm, and the dislocations subtend an angle that is between about 20 degrees and about 70 degrees relative to a [110] crystallographic plane.

Disclosed embodiments are advantageous because they provide semiconductor device structures 100a with improved source/drain features (232S, 232D) and improved contact epitaxial layers 118. In this regard, a source/drain feature (232S, 232D) is formed by performing an epitaxial deposition process at a first temperature, and a contact epitaxial layer 118 is formed by performing a second epitaxial deposition process at a second temperature that is about 20% to about 30% lower than the first temperature. High-quality device structures (100a, 1100a, 1100b, 1100c, 1100d), with few dislocations 402, amorphous material 502, and dopant precipitates 406 are obtained by controlling process conditions according to various disclosed embodiments (1300, 1400).

According to various embodiments, a method of forming a semiconductor device includes forming a gate-all-around field-effect transistor including a plurality of stacked channel layers and a source/drain region, performing a deposition process at a first temperature to form a first epitaxial layer over the source/drain region such that ends of the plurality of stacked channel layers are in contact with the first epitaxial layer, and performing a second deposition process at a second temperature to form a second epitaxial layer that contacts the first epitaxial layer, such that the second temperature is 20% to 30% lower than the first temperature. According to various embodiments, the method further includes forming a contact etch stop layer over the first epitaxial layer, forming a contact opening in the first epitaxial layer, and forming the second epitaxial layer after forming the contact opening. According to various embodiments, the method further includes forming a contact etch stop layer over the first epitaxial layer, forming a contact opening in the first epitaxial layer, and forming the second epitaxial layer after forming the contact opening. According to various embodiments, the first epitaxial layer includes a first dopant concentration, the second epitaxial layer includes a second dopant concentration that is greater than the first dopant concentration, and the second epitaxial layer is formed after the first epitaxial layer.

According to various embodiments, forming the first epitaxial layer further includes depositing a first layer of n-type doped silicon, and forming the second epitaxial layer further includes depositing a second layer of n-type doped silicon over the first epitaxial layer. According to various embodiments, the method includes forming an isolation structure over the source/drain region and forming the first epitaxial layer over the isolation structure. According to various embodiments, the first epitaxial layer further includes a first concentration of phosphorous that is between 5×10²⁰ atom/cm³ and 5×10²¹ atom/cm³, and the second epitaxial layer further includes a second concentration of phosphorus that is between 1×10²¹ atom/cm³ and 7×10²¹ atom/cm³. According to various embodiments, depositing the first epitaxial layer further includes performing a first metal-organic chemical-vapor deposition (MOCVD) process using a first mixture of two or more of SiH₄, H₂SiCl₂, HCl, and GeH₄ precursor gases, and depositing the second epitaxial layer further includes performing a second MOCVD deposition process using a second mixture of two or more of SiH₄, Si₂H₆, Si₃H₈, H₂SiCl₂, HCl, and Cl₂ precursor gases.

According to various embodiments, depositing the first epitaxial layer further includes performing the first MOCVD deposition process such that the first temperature is between 500° C. and 850° C., and depositing the second epitaxial layer further includes performing the second MOCVD deposition process such that the second temperature is between 350° C. and 680° C. According to various embodiments, forming the first epitaxial layer further includes depositing a first p-type doped SiGe alloy layer, and forming the second epitaxial layer further includes depositing a second p-type doped SiGe alloy layer over the first epitaxial layer.

According to various embodiments, the first epitaxial layer includes SiₓGe₁₋ₓ, where x is between 0.4 and 0.6, and the second epitaxial layer includes SiₓGe₁₋ₓ, where x is between 0.05 and 0.5. According to various embodiments, the first epitaxial layer includes a first concentration of boron that is between 7×10²⁰ atom/cm³ and 1×10²¹ atom/cm³, and the second epitaxial layer includes a second concentration of boron that is between 1×10²⁰ atom/cm³ and 7×10²¹ atom/cm³. According to various embodiments, depositing the first epitaxial layer further includes performing a first MOCVD deposition process using a first mixture of two or more of SiH₄, H₂SiCl₂, HCl, and GeH₄ precursor gases, and depositing the second epitaxial layer further includes performing a second MOCVD deposition process using a second mixture of two or more of SiH₄, Si₂H₆, Si₃H₈, H₂SiCl₂, HCl, Cl₂, GeH₄, and Ge₂H₆ precursor gases. According to various embodiments, depositing the first epitaxial layer further includes performing the first MOCVD deposition process such that the first temperature is between 500° C. and 850° C., and depositing the second epitaxial layer further includes performing the second MOCVD deposition process such that the second temperature is between 320° C. and 680° C.

According to various embodiments, a method of forming a semiconductor device includes forming a plurality of stacked semiconductor nanostructures configured as channel layers, forming a source/drain region adjacent to ends of the channel layers, forming a gate structure that surrounds each channel region, performing a first deposition process at a first temperature to form a first epitaxial layer over the source/drain region and in contact with each of the plurality of stacked semiconductor nanostructures, performing a second deposition process at a second temperature to form a frontside contact epitaxial layer over the first epitaxial layer such that the second temperature is 20% to 30% lower than the first temperature, and performing a third deposition process at a third temperature to form a backside contact epitaxial layer over the first epitaxial layer such that the third temperature is 20% to 30% lower than the first temperature.

According to various embodiments, the first epitaxial layer includes a first dopant concentration, the frontside contact epitaxial layer and the backside contact epitaxial layer each include a second dopant concentration that is greater than the first dopant concentration, and the frontside contact epitaxial layer is formed after the first epitaxial layer and the backside contact epitaxial layer is formed after the frontside contact epitaxial layer. According to various embodiments, the first epitaxial layer includes a first n-type doped silicon layer having a first concentration of phosphorous that is between 5×10²⁰ atom/cm³ and 5×10²¹ atom/cm³, and the frontside contact epitaxial layer and the backside contact epitaxial layer each include a second n-type doped silicon layer having a second concentration of phosphorous that is between 1×10²¹ atom/cm³ and 7×10²¹ atom/cm³.

According to various embodiments, the first epitaxial layer includes SiₓGe₁₋ₓ, where x is between 0.4 and 0.6 and a first concentration of boron that is between 7×10²⁰ atom/cm³ and 1×10²¹ atom/cm³, and the frontside contact epitaxial layer and the backside contact epitaxial layer each include SiₓGe₁₋ₓ, where x is between 0.05 and 0.5 and a second concentration of boron that is between 1×10²⁰ atom/cm³ and 7×10²¹ atom/cm³. According to various embodiments, depositing the first epitaxial layer further includes performing the first deposition process such that the first temperature is between 500° C. and 850° C., and depositing the frontside contact epitaxial layer and the backside contact epitaxial layer further includes performing the second deposition process and the third deposition process such that the second temperature and the third temperature are each between 350° C. and 680° C. According to various embodiments, the method further includes forming a front contact, forming a back contact, and forming a silicide layer between at least one of the frontside contact epitaxial layer and the front contact or between the backside contact epitaxial layer and the back contact, such that the silicide layer has a thickness that is less than 10 nm.

According to various embodiments, a semiconductor device includes a transistor structure including a channel layer and a source/drain region, a first epitaxial layer formed over the source/drain region such that the first epitaxial layer is in contact with the channel layer, a second epitaxial layer that is in contact with the first epitaxial layer, and an electrically conductive contact connected to the second epitaxial layer such that the second epitaxial layer is between the second epitaxial layer and the electrically conductive contact. According to various embodiments, the first epitaxial layer includes a crystalline structure with a first dopant concentration that is between 5×10²⁰ atom/cm³ and 5×10²¹ atom/cm³, and the second epitaxial layer includes a crystalline structure with a second dopant concentration that is greater than the first dopant concentration and is between 1×10²⁰ atom/cm³ and 7×10²¹ atom/cm³, such that the second epitaxial layer includes fewer than 50 dislocations. According to various embodiments, the second epitaxial layer is substantially free of dopant precipitates. According to various embodiments, the semiconductor device of claim 18, further includes dislocations extending within the first epitaxial layer and the second epitaxial layer having a length that is between 1 nm and 40 nm, and such that the dislocations subtend an angle that is between 20 degrees and 70 degrees relative to a [110] crystallographic plane.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of forming a semiconductor device, comprising:
forming a gate-all-around field-effect transistor comprising a plurality of stacked channel layers and a source/drain region;
performing a deposition process at a first temperature to form a first epitaxial layer over the source/drain region such that ends of the plurality of stacked channel layers are in contact with the first epitaxial layer; and
performing a second deposition process at a second temperature to form a second epitaxial layer that contacts the first epitaxial layer,
wherein the second temperature is 20% to 30% lower than the first temperature.

2. The method of claim 1, further comprising:
forming a contact etch stop layer over the first epitaxial layer;
forming a contact opening in the first epitaxial layer; and
forming the second epitaxial layer after forming the contact opening,
wherein:
the first epitaxial layer comprises a first dopant concentration;
the second epitaxial layer comprises a second dopant concentration that is greater than the first dopant concentration; and
the second epitaxial layer is formed after the first epitaxial layer.

3. The method of claim 1, wherein:
forming the first epitaxial layer further comprises depositing a first layer of n-type doped silicon; and
forming the second epitaxial layer further comprises depositing a second layer of n-type doped silicon over the first epitaxial layer.

4. The method of claim 3, further comprising:
forming an isolation structure over the source/drain region; and
forming the first epitaxial layer over the isolation structure.

5. The method of claim 3, wherein:
the first epitaxial layer further comprises a first concentration of phosphorous that is between 5×10²⁰ atom/cm³ and 5×10²¹ atom/cm³; and
the second epitaxial layer further comprises a second concentration of phosphorus that is between 1×10²¹ atom/cm³ and 7×10²¹ atom/cm³.

6. The method of claim 1, wherein:
depositing the first epitaxial layer further comprises performing a first metal-organic chemical-vapor deposition (MOCVD) process using a first mixture of two or more of SiH₄, H₂SiCl₂, HCl, and GeH₄ precursor gases; and
depositing the second epitaxial layer further comprises performing a second MOCVD deposition process using a second mixture of two or more of SiH₄, Si₂H₆, Si₃H₈, H₂SiCl₂, HCl, or Cl₂ precursor gases.

7. The method of claim 6, wherein:
depositing the first epitaxial layer further comprises performing the first MOCVD deposition process such that the first temperature is between 500° C. and 850° C.; and
depositing the second epitaxial layer further comprises performing the second MOCVD deposition process such that the second temperature is between 350° C. and 680° C.

8. The method of claim 1, wherein:
forming the first epitaxial layer further comprises depositing a first p-type doped SiGe alloy layer; and
forming the second epitaxial layer further comprises depositing a second p-type doped SiGe alloy layer over the first epitaxial layer.

9. The method of claim 8, wherein:
the first epitaxial layer comprises SiₓGe₁₋ₓ, where x is between 0.4 and 0.6; and
the second epitaxial layer comprises SiₓGe₁₋ₓ, where x is between 0.05 and 0.5.

10. The method of claim 9, wherein:
the first epitaxial layer comprises a first concentration of boron that is between 7×10²⁰ atom/cm³ and 1×10²¹ atom/cm³; and
the second epitaxial layer comprises a second concentration of boron that is between 1×10²⁰ atom/cm³ and 7×10²¹ atom/cm³.

11. The method of claim 8, wherein:
depositing the first epitaxial layer further comprises performing a first MOCVD deposition process using a first mixture of two or more of SiH₄, H₂SiCl₂, HCl, and GeH₄ precursor gases; and
depositing the second epitaxial layer further comprises performing a second MOCVD deposition process using a second mixture of two or more of SiH₄, Si₂H₆, Si₃H₈, H₂SiCl₂, HCl, Cl₂, GeH₄, and Ge₂H₆ precursor gases.

12. The method of claim 11, wherein:
depositing the first epitaxial layer further comprises performing the first MOCVD deposition process such that the first temperature is between 500° C. and 850° C.; and
depositing the second epitaxial layer further comprises performing the second MOCVD deposition process such that the second temperature is between 320° C. and 680° C.

13. A method of forming a semiconductor device, comprising:
forming a plurality of stacked semiconductor nanostructures configured as channel layers;
forming a source/drain region adjacent to ends of the channel layers;
forming a gate structure that surrounds each channel layer;
performing a first deposition process at a first temperature to form a first epitaxial layer over the source/drain region and in contact with each of the plurality of stacked semiconductor nanostructures;
performing a second deposition process at a second temperature to form a frontside contact epitaxial layer over the first epitaxial layer such that the second temperature is 20% to 30% lower than the first temperature; and
performing a third deposition process at a third temperature to form a backside contact epitaxial layer over the first epitaxial layer such that the third temperature is 20% to 30% lower than the first temperature,
wherein:
the first epitaxial layer comprises a first dopant concentration;
the frontside contact epitaxial layer and the backside contact epitaxial layer each comprise a second dopant concentration that is greater than the first dopant concentration; and
the frontside contact epitaxial layer is formed after the first epitaxial layer and the backside contact epitaxial layer is formed after the frontside contact epitaxial layer.

14. The method of claim 13, wherein:
the first epitaxial layer comprises a first n-type doped silicon layer comprising a first concentration of phosphorous that is between 5×10²⁰ atom/cm³ and 5×10²¹ atom/cm³; and
the frontside contact epitaxial layer and the backside contact epitaxial layer each comprise a second n-type doped silicon layer comprising a second concentration of phosphorous that is between 1×10²¹ atom/cm³ and 7×10²¹ atom/cm³.

15. The method of claim 13, wherein:
the first epitaxial layer comprises SiₓGe₁₋ₓ, where x is between 0.4 and 0.6 and a first concentration of boron that is between 7×10²⁰ atom/cm³ and 1×10²¹ atom/cm³; and
the frontside contact epitaxial layer and the backside contact epitaxial layer each comprise SiₓGe₁₋ₓ, where x is between 0.05 and 0.5 and a second concentration of boron that is between 1×10²⁰ atom/cm³ and 7×10²¹ atom/cm³.

16. The method of claim 13, wherein:
depositing the first epitaxial layer further comprises performing the first deposition process such that the first temperature is between 500° C. and 850° C.; and
depositing the frontside contact epitaxial layer and the backside contact epitaxial layer further comprises performing the second deposition process and the third deposition process such that the second temperature and the third temperature are each between 350° C. and 680° C.

17. The method of claim 13, further comprising:
forming a front contact;
forming a back contact; and
forming a silicide layer between at least one of the frontside contact epitaxial layer and the front contact or between the backside contact epitaxial layer and the back contact,
wherein the silicide layer comprises a thickness that is less than 10 nm.

18. A semiconductor device, comprising:
a transistor structure comprising a channel layer and a source/drain region;
a first epitaxial layer formed over the source/drain region such that the first epitaxial layer is in contact with the channel layer;
a second epitaxial layer that is in contact with the first epitaxial layer; and
an electrically conductive contact connected to the second epitaxial layer such that the second epitaxial layer is between the second epitaxial layer and the electrically conductive contact,
wherein:
the first epitaxial layer comprises a crystalline structure with a first dopant concentration that is between 5×10²⁰ atom/cm³ and 5×10²¹ atom/cm³; and
the second epitaxial layer comprises a crystalline structure with a second dopant concentration that is greater than the first dopant concentration and is between 1×10²⁰ atom/cm³ and 7×10²¹ atom/cm³,
wherein the second epitaxial layer comprises fewer than 50 dislocations.

19. The semiconductor device of claim 18, wherein the second epitaxial layer is substantially free of dopant precipitates.

20. The semiconductor device of claim 18, further comprising:
dislocations extending within the first epitaxial layer and the second epitaxial layer having a length that is between 1 nm and 40 nm,
wherein the dislocations subtend an angle that is between 20 degrees and 70 degrees relative to a [110] crystallographic plane.
